(19) United States
(12) Patent Application Publication
(10) Pub. No.: US 2023/0317687 A1
(43) Pub. Date: Oct. 5, 2023

(54) MICRO-LED DISPLAY ARCHITECTURE FOR HIGH VOLUME MANUFACTURING

(71) Applicant: Intel Corporation, Santa Clara, CA (US)

(72) Inventors: Bhupendra KUMAR, Beaverton, OR (US); Khaled AHMED, San Jose, CA (US); Andrew William KEATES, Los Gatos, CA (US); Jay GUPTA, Hillsboro, OR (US)

(21) Appl. No.: 17/710,662

(22) Filed: Mar. 31, 2022

(51) Int. Cl. H01L 25/075; H01L 33/62

(52) U.S. Cl. CPC H01L 25/0753; H01L 2933/0066; H01L 33/62

(57) ABSTRACT

Embodiments disclosed herein include a display. In an embodiment, the display comprises a backplane, and circuitry on the backplane. In an embodiment, a pad with a first width is over the backplane and electrically coupled to the circuitry. In an embodiment, the pad comprises a conductive material. In an embodiment, the display further comprises a light emitting diode (LED) coupled to the pad, where the LED has a second width that is smaller than the first width.

### TECHNICAL FIELD

Embodiments of the present disclosure relate to electronic devices, and more particularly to displays that include micro light emitting diodes (LEDs) that are mounted to contacts with footprints that are greater than footprints of the micro-LEDs.

### BACKGROUND

There have been significant advances in display technology over the past decades. One solution for display technology is a light emitting diode (LED) display. In an LED display, the pixels are broken into subpixels that include, generally, a red LED, a green LED, and a blue LED to provide a red, green, blue (RGB) pixel. Though, it is to be appreciated that the number of subpixels and their respective colors can be varied depending on the given display. One approach that has been gaining popularity is the use of micro-LED displays. In a micro-LED display, each subpixel comprises an individual LED that is fabricated on a source wafer and ultimately mounted to the backplane substrate.

As can be imagined, the sheer number of micro-LEDs that need to be transferred results in a significant manufacturing challenge. The current approach for mass transfer of micro-LEDs from source wafers to backplane substrate has the receiving backplane pad smaller than the micro-LED size. This prevents any interaction of adjacent micro-LEDs during the bonding process. This design was proposed in order to enable source wafers to be used to populate multiple backplane displays using a single source wafer. For example, a 5 μm micro-LED may be designed to land on a 4 μm pad on the backplane.

With advanced mounting technologies, the misalignment error may be approximately 0.5 μm. However, this does not account for incoming material variabilities which may introduce an additional run out misalignment error of 2 μm to 3 μm. This error cannot be easily corrected during the bonding process. This leads to misalignment during transfer, damaged during transfer, or, in the worst case scenario, no transfer of micro-LEDs to the backplane at all.

### BRIEF DESCRIPTION OF THE DRAWINGS

FIG. 1A is a cross-sectional illustration of a source wafer aligned over a backplane with pads that have a dimension that is smaller than a dimension of the micro-light emitting diodes (LEDs) on the source wafer.

FIG. 1B is a cross-sectional illustration of the source wafer engaged with the backplane with perfect alignment.

FIG. 1C is a cross-sectional illustration of the source wafer engaged with the backplane with a misalignment.

FIG. 2A is a cross-sectional illustration of a source wafer aligned over a backplane with pads that have a dimension that is greater than a dimension of the micro-LEDs on the source wafer, in accordance with an embodiment.

FIG. 2B is a cross-sectional illustration of the source wafer engaged with the backplane with perfect alignment, in accordance with an embodiment.

FIG. 2C is a cross-sectional illustration of the source wafer engaged with the backplane with a misalignment, in accordance with an embodiment.

FIG. 2D is a cross-sectional illustration of the source wafer being retracted after the transfer of micro-LEDs to the backplane, in accordance with an embodiment.

FIG. 3 is a cross-sectional illustration of a source wafer that is engaged with the backplane and the laser power being applied to the selected micro-LEDs that are to be transferred, in accordance with an embodiment.

FIG. 4 is a cross-sectional illustration of a backplane with circuitry, a pad coupled to the circuitry, and a micro-LED coupled to the pad, in accordance with an embodiment.

FIG. 5A is a plan view illustration of a pad and a perfectly aligned micro-LED that can be used as a box-in-box alignment feature, in accordance with an embodiment.

FIG. 5B is a plan view illustration of a pad and a misaligned micro-LED that can be used as a box-in-box alignment feature, in accordance with an embodiment.

FIG. 6A is a cross-sectional illustration of a source wafer aligned over a first backplane, in accordance with an embodiment.

FIG. 6B is a cross-sectional illustration of the source wafer engaged with the first backplane, in accordance with an embodiment.

FIG. 6C is a cross-sectional illustration depicting the laser exposure of selected ones of the micro-LEDs, in accordance with an embodiment.

FIG. 6D is a cross-sectional illustration of the source wafer being retracted and leaving behind transferred micro-LEDs, in accordance with an embodiment.

FIG. 6E is a cross-sectional illustration of the source wafer aligned over a second backplane, in accordance with an embodiment.

FIG. 6F is a cross-sectional illustration of the source wafer engaged with the second backplane, in accordance with an embodiment.

FIG. 6G is a cross-sectional illustration depicting the laser exposure of selected ones of the micro-LEDs, in accordance with an embodiment.

FIG. 6H is a cross-sectional illustration of the source wafer being retracted and leaving behind transferred micro-LEDs, in accordance with an embodiment.

FIG. 7 is a plan view illustration of a display device that comprises subpixels that include a micro-LED on a pad, where the footprint of the pad is bigger than a footprint of the micro-LED, in accordance with an embodiment.

FIG. 8 is a schematic of a computing device built in accordance with an embodiment.

### EMBODIMENTS OF THE PRESENT DISCLOSURE

Described herein are electronic devices with displays that include micro light emitting diodes (LEDs) that are mounted to contacts with footprints that are greater than footprints of the micro-LEDs, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, existing micro-LED transfer processes rely on pads on the backplane that have a footprint that is smaller than a footprint of the micro-LED. However, such architectures make alignment and micro-LED transfer difficult. The assembly difficulties may render a given product not suitable for high volume manufacturing (HVM). Accordingly, embodiments disclosed herein include architectures that are more compatible with HVM solutions. Particularly, embodiments include pads on the backplane that have a dimension (e.g., width) that is larger than a dimension (e.g., width) of the micro-LED. In such embodiments, the larger footprint of the pad allows for larger misalignments in the system (e.g., attributable to either alignment tolerances and/or to material manufacturing tolerances at the source wafer and the backplane).

In addition to providing improvements in alignment tolerance, embodiments may also aid in protecting the backplane circuitry from laser exposure during the micro-LED release process. The resulting structure also produces a box-in-box alignment feature that can be used to improve alignment accuracy of the post transfer anode contact fabrication to complete the display device fabrication. Furthermore, the larger pad topology will function as a heat sink during the selective laser release process and facilitate in-situ local bond annealing, which enhances the bond strength and reliability of the display.

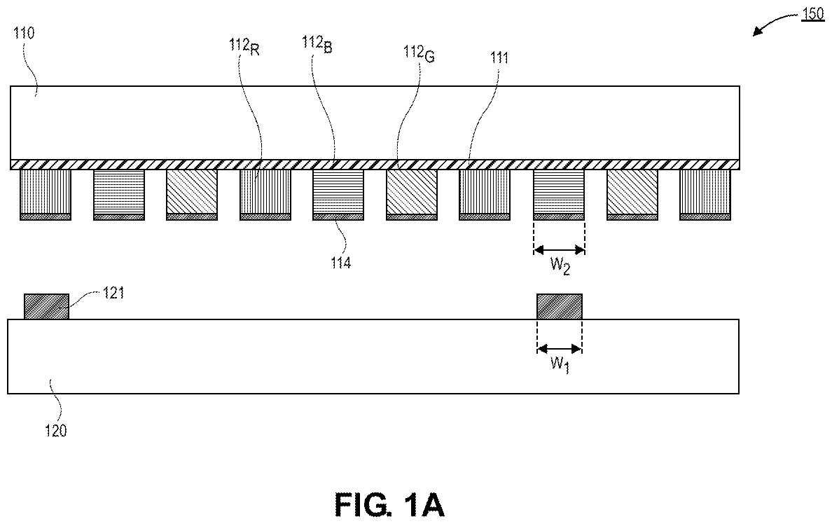

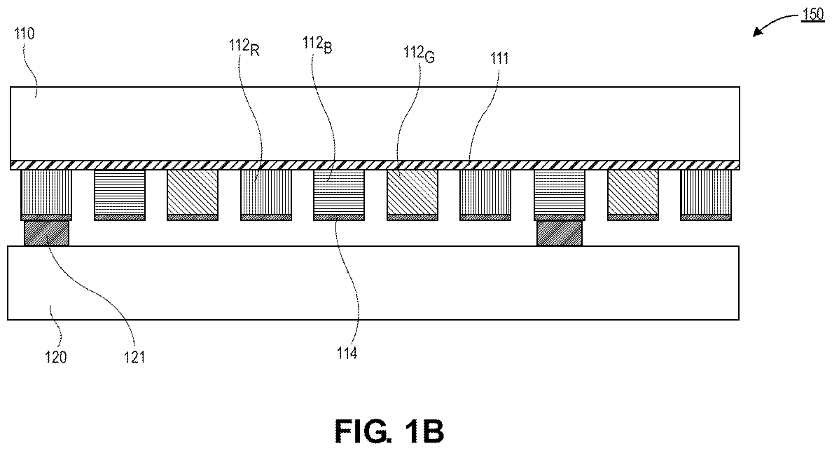

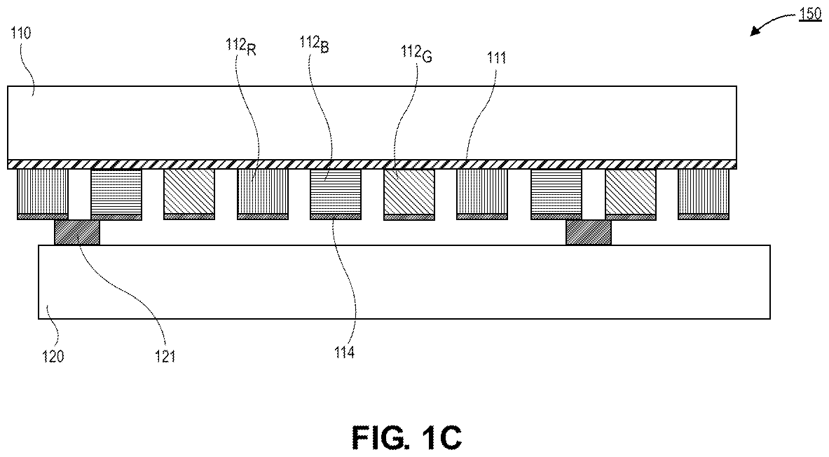

To provide additional context, FIGS. 1A-1C provide cross-sectional illustrations of an assembly 150 for transferring micro-LEDs 112 from a source wafer 110 to a backplane 120. The micro-LEDs 112 may include red micro-LEDs 112_{R}, green micro-LEDs 112_{G}, and blue micro-LEDs 112_{B}. The source wafer 110 may be a semiconductor wafer, such as a silicon wafer. In some instances the form factor of the semiconductor wafer may be a 200 mm or a 300 mm wafer. The backplane 120 may be a glass backplane 120. Conductive circuitry (not shown) may be provided on and/or in the backplane 120. The conductive circuitry may be electrically coupled to pads 121 on a surface of the backplane 120.

As shown in FIG. 1A, the pads 121 have a first width W₁ and the micro-LEDs 112 have a second width W₂. Typically, the first width W₁ is smaller than the second width W₂. This prevents neighboring micro-LEDs 112 from interfering with the bonding process. For example, the second width W₂ may be approximately 5 μm or smaller, and the first width W₁ may be approximately 4 μm or smaller. Though, it is to be appreciated that other form factors for the micro-LEDs 112 and the pads 121 may be provided, depending on the design of the device. As used herein, “approximately” may refer to a range of values that are within 10 percent of the stated value. For example, approximately 1 μm may refer to a range from 0.9 μm to 1.1 μm.

The source wafer 110 may be aligned with respect to the backplane 120. For example, mechanical structures (not shown) may secure the source wafer 110 and the backplane 120. The mechanical structures may be displaceable in order to orient the source wafer 110 so that a set of micro-LEDs 112 are aligned over the pads 121.

Referring now to FIG. 1B, a cross-sectional illustration of the assembly 150 after the source wafer 110 is brought towards the backplane 120 is shown. The source wafer 110 may be displaced towards the backplane 120 until the micro-LEDs 112 contact the pad 121. For example, conductive layers 114 on the micro-LEDs 112 may directly contact the pad 121. A bonding process (e.g., diffusion bonding) may secure the micro-LEDs 112 to the pads 121. In some instances, the backside of the micro-LEDs 112 may be released from the source wafer 110 by deactivating a release layer 111 over the micro-LEDs 112. As will be described in greater detail below, the release layer 111 may be deactivated by a laser exposure process.

In FIG. 1B, the source wafer 110 is aligned with the backplane 120 so that the micro-LEDs 112 are perfectly aligned with the underlying pads 121. That is, each pad 121 is perfectly aligned with the overlying micro-LED 112 so that the pad 121 is centered with the micro-LED 112. Such an assembly process is ideal, but it is typically not possible to ensure such alignment accuracy. For example, the mechanical structures may have an alignment tolerance (e.g., approximately 0.5 μm). Additionally, there may be misalignment between the location of the micro-LEDs 112 and the pads 121 due to material fabrication tolerances (e.g., approximately 1 μm to approximately 3 μm).

As such, the pads 121 may be off-center from the micro-LEDs 112. An example of such an architecture 150 is shown in FIG. 1C. As shown, the pads 121 are provided between the micro-LEDs 112. For example, each pad 121 may be contacting a pair of micro-LEDs 112. The micro-LED 112 that is desired to be attached to the pad 121 may even be overhanging an edge of the pad 121. As such, the connection to the pad 121 is suboptimal, and can result in manufacturing defects or otherwise decreased robustness of the display device.

Accordingly, embodiments disclosed herein include display topologies where the pads have a width that is wider than the width of the micro-LEDs. Such a configuration may be referred to as a top-hat configuration since the cross-section of the pad and the micro-LED form a top-hat like shape with a wider bottom (i.e., the pad) and a narrower top (i.e., the micro-LED). The wider pads allow for more misalignment tolerance and provide robust structures that are compatible with HVM processes.

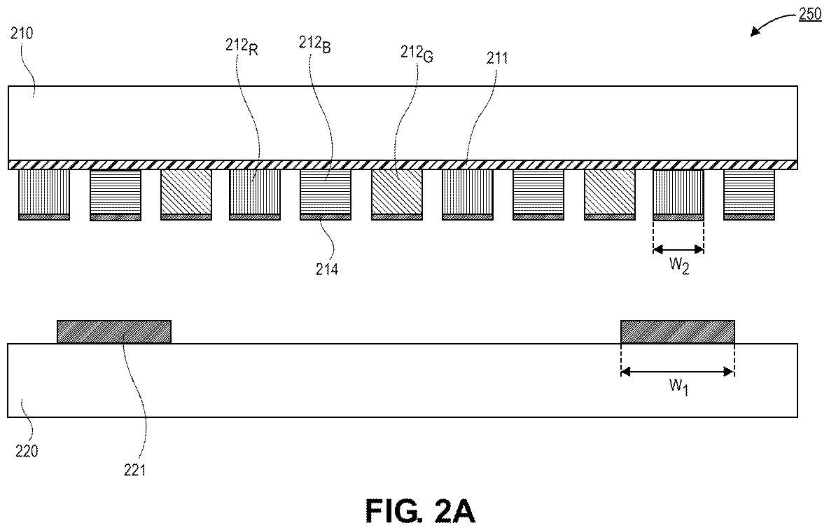

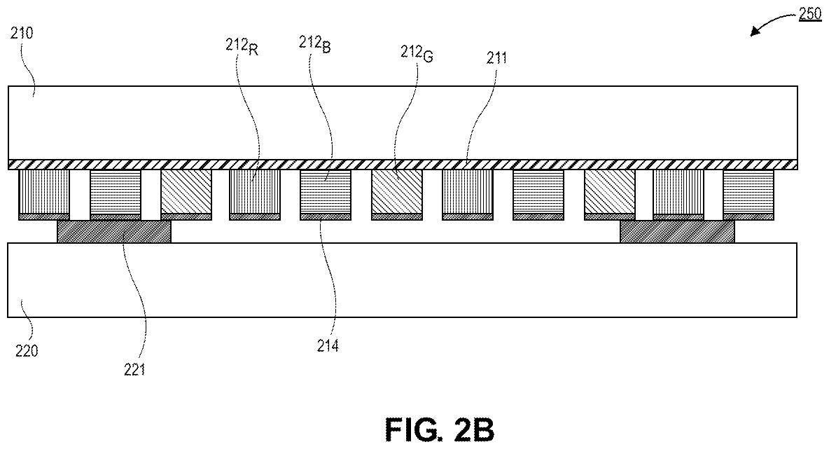

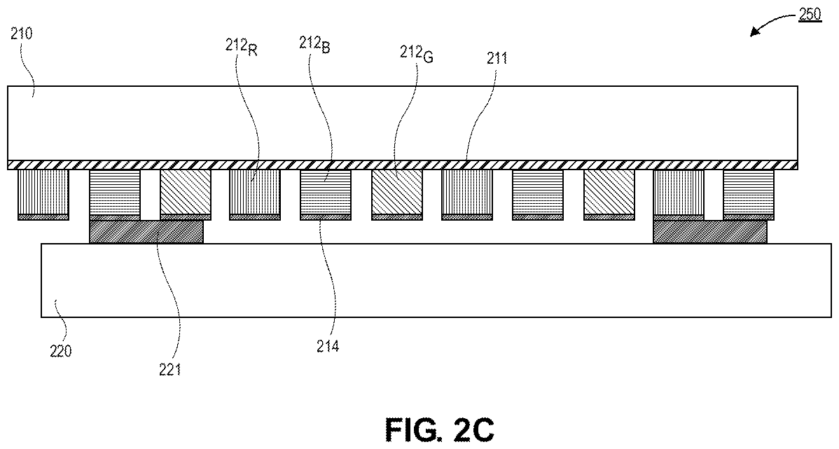

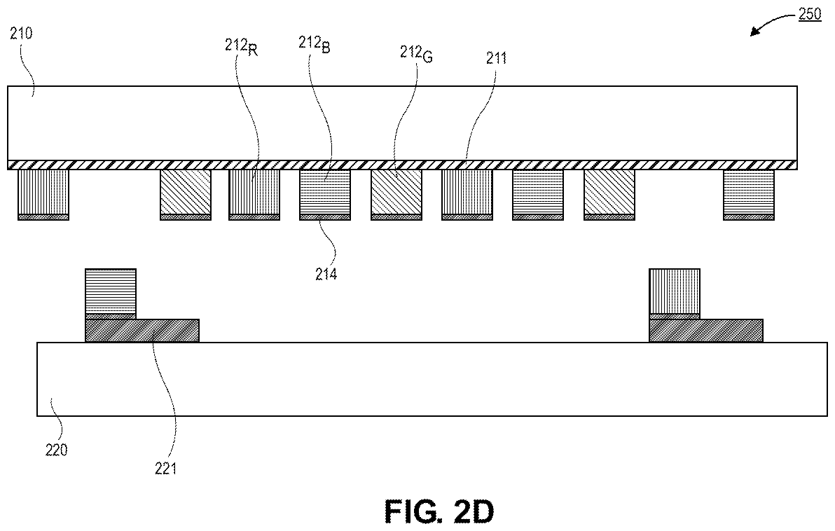

Referring now to FIG. 2A, a cross-sectional illustration of an assembly 250 is shown, in accordance with an embodiment. In an embodiment, the assembly 250 comprises a source wafer 210 that is aligned over a backplane 220. The source wafer 210 and the backplane 220 may be secured by mechanical structures that allow for displacement of the source wafer 210 relative to the backplane 220. In some embodiments, the source wafer 210 is displaceable, and the backplane 220 is held stationary. In other embodiments, the source wafer 210 and the backplane 220 are both displaceable relative to each other.

In an embodiment, the source wafer 210 may be a semiconductor wafer, such as a silicon wafer. The micro-LEDs 212 may be grown (or otherwise fabricated) on the source wafer 210. The source wafer 210 may have a form factor typical of semiconductor wafers. For example, the source wafer 210 may be a 200 mm wafer or a 300 mm wafer. Though, it is to be appreciated that other form factors may also be used, in accordance with additional embodiments.

In an embodiment, the micro-LEDs 212 may comprise red micro-LEDs 212_{R}, blue micro-LEDs 212_{B}, and green micro-LEDs 212_{G}. In other embodiments different color micro-LEDs 212 may also be included. The micro-LEDs 212 may be grown over a release layer 211 on the source wafer 210. The release layer 211 may be an inorganic material layer on which the micro-LEDs 212 may be grown. The release layer 211 may be deactivated with a laser exposure process, as will be described in greater detail below. A conductive layer 214 may be provided on a bottom surface of the micro-LEDs 212. The conductive layer 214 may be a layer suitable for bonding with the pad 221 on the backplane 220. To ensure proper bonding, a surface roughness of the conductive layer 214 may be approximately 0.5 nm or less. In an embodiment, a thickness of the micro-LEDs 212 may be approximately 2 μm or less. The conductive layer 214 may comprise copper or any other suitable conductive material.

In an embodiment, the backplane 220 may be a glass backplane 220. The backplane 220 may have a form factor that is different than the form factor of the source wafer 210. For example, the backplane 220 may be larger than the source wafer 210 or smaller than the source wafer 210. In some embodiments, the backplane 220 may be a rectangular backplane 220. The backplane 220 may have a form factor for forming mobile displays (e.g., for mobile phone architectures) or a form factor for forming television displays and/or monitor displays.

In an embodiment, pads 221 may be provided on a surface of the backplane 220. The pads 221 may be electrically coupled to circuitry (not shown) on and/or in the backplane 220. In an embodiment, the pads 221 may have a surface roughness that is approximately 0.5 nm or less in order to provide improved bonding with the micro-LEDs 212. The pads 221 may be any suitable conductive material. For example, the pads 221 may comprise copper or the like. In an embodiment, a thickness of the pads 221 may be approximately 0.5 μm or less.

The pads 221 may have a first width W₁. In an embodiment, the micro-LEDs 212 may have a second width W₂. The first width W₁ may be larger than the second width W₂. In some embodiments, the first width W₁ may be at least approximately 1.5 times larger than the second width W₂. In other embodiments, the first width W₁ may be at least approximately 2.0 times larger than the second width W₂. For example, the first width W₁ may be approximately 10 μm and the second width W₂ may be approximately 5 μm.

Referring now to FIG. 2B, a cross-sectional illustration of the assembly 250 after the source wafer 210 is displace towards the backplane 220 is shown, in accordance with an embodiment. In an embodiment, the source wafer 210 is displaced towards the backplane 220 until the micro-LEDs 212 contact the pad 221. As shown, the larger size of the pads 221 results in multiple micro-LEDs 212 contacting the pad 221. However, it is to be appreciated that the laser release process will only release the targeted micro-LED 212, as will be described in greater detail below. In an embodiment, three micro-LEDs 212 are provided on each of the pads 221. However, only the central micro-LED 212_{B} (on the left side) and the central micro-LED 212_{R} (on the right side) will be released onto the pads 221.

In FIG. 2B, the alignment of the source wafer 210 to the backplane 220 is perfect. That is, the targeted micro-LEDs 212 that are to be released are perfectly centered on the pads 221. However, the benefit of larger pads 221 becomes more apparent when there is a misalignment between the source wafer 210 and the backplane 220. An example of a misaligned assembly 250 is shown in the embodiment depicted in FIG. 2C.

As shown in FIG. 2C, the source wafer 210 is shifted over to the left relative to the backplane 220. As such, the targeted micro-LEDs 212 are off-center from the pads 221. However, due to the larger width of the pads 221, the targeted micro-LEDs 212 are still entirely within a footprint of the pads 221. As such, the bond between the micro-LED 212 and the pad 221 still remains robust, compared to the architecture shown in FIG. 1C where the micro-LED 112 hangs off the edge of the pad 112. As such, the alignment tolerance is improved. This allows for easier assembly and renders the assembly process more suitable for HVM processes.

Referring now to FIG. 2D, a cross-section of the assembly 250 after the targeted micro-LEDs 212 are released and the source wafer 210 is retracted is shown, in accordance with an embodiment. In an embodiment, the targeted micro-LEDs 212 may be released by exposing the release layer 211 over the target micro-LEDs 212 with a laser, as will be described in greater detail below. The release layer 211 is modified so that the micro-LED 212 can be released from the source wafer 210. Additionally, the conductive layer 214 bonds to the pad 221. For example, a solid state diffusion bonding process may be used to bond the conductive layer 214 to the pad 221.

As illustrated in FIG. 2D, the released micro-LEDs 212 are offset from the underlying pads 221. In the particular embodiment shown, the micro-LEDs 212 are at an edge of the underlying pads 221. However, depending on the alignment accuracy between the source wafer 210 and the backplane 220, the micro-LEDs 212 may be provided at any location on the pads 221. That is, there is improved flexibility to provide a robust connection between the micro-LEDs 212 and the pads 221.

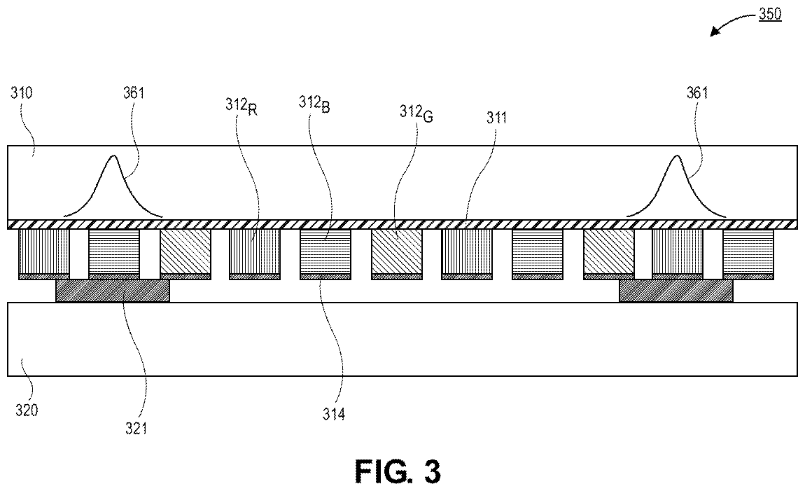

Referring now to FIG. 3, a cross-sectional illustration of an assembly 350 is shown, in accordance with an embodiment. In an embodiment, the assembly 350 may comprise a source wafer 310. Micro-LEDs 312_{R}, 312_{B}, and 312_{G} may be attached to the source wafer 310 by a release layer 311. Conductive layers 314 may be provided along a bottom surface of the micro-LEDs 312. In an embodiment, a backplane 320 may be provided below the source wafer 310. The backplane 320 may include pads 321. In an embodiment, the source wafer 310 is positioned so that micro-LEDs 312 are contacting the pads 321.

In an embodiment, a laser release process is used in order to release selected ones of the micro-LEDs 312 for bonding to the pads 321. The laser may be an IR laser. As shown, the laser pulse 361 may have a Gaussian distribution. It is to be appreciated that the larger pad 321 width allows for improved performance of the laser release process. In part, this is because the pads 321 block the laser exposure from interacting with the underlying circuitry (not shown) below the pads 321. For example, approximately 90% or more of the energy from the laser is blocked by the micro-LED 312 and the pad 321. As shown in FIG. 3, the tail ends of the laser pulse 361 are substantially within a footprint of the pad 321. As such, the laser energy does not propagate through to the underlying circuitry. This prevents damage to the circuitry and enables a more robust device.

Additionally, the pads 321 can function as a heatsink during the selective laser release. This heatsink feature facilitates an in-situ local bond annealing, which enhances the bond strength and reliability of the display. Particularly, the pads 321 absorb laser energy which heats the pads 321. The increased heat of the pads 321 provides energy to anneal the bond between the pad 321 and the conductive layer 314 of the micro-LED 312. As such, a more robust connection is enabled.

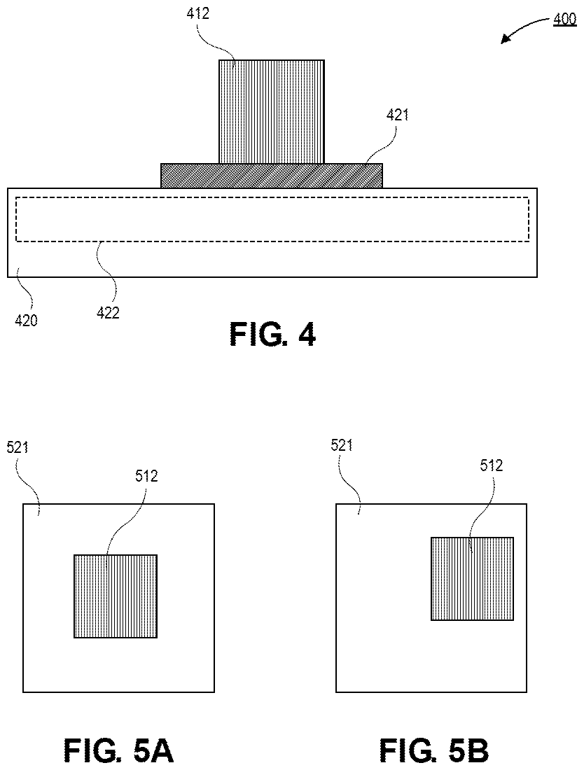

Referring now to FIG. 4, a cross-sectional illustration of a portion of a display 400 is shown, in accordance with an embodiment. In an embodiment, the display 400 comprises a backplane 420. The backplane 420 may be a glass backplane 420. Additionally, conductive circuitry 422 (indicated generically with a dashed box) is provided on and/or in the backplane 420. In an embodiment, the conductive circuitry 422 may be electrically coupled to a pad 421. The pad 421 may be electrically coupled to a micro-LED 412. For example, diffusion bonding between the pad 421 and a conductive layer (not shown) on the micro-LED 412 may electrically and mechanically couple the micro-LED 412 to the pad 421.

As shown, the width of the pad 421 is greater than a width of the micro-LED 412. For example, the width of the pad 421 may be at least approximately 1.5 times greater than the width of the micro-LED 412, or the width of the pad 421 may be at least approximately two times greater than the width of the micro-LED 412. As such, there is increased margin to accommodate misalignment between the micro-LED 412 and the pad 421.

In an embodiment, the difference in the widths of the micro-LED 412 and the pad 421 may give rise to a top-hat like structure. That is, the pad 421 may be the base of the top-hat shape, and the micro-LED 412 may be the top of the top-hat shape. In the illustrated embodiment, the micro-LED 412 is perfectly centered on the pad 421. However, in other embodiments, the micro-LED 412 may be offset from the center of the pad 421.

In an embodiment, the thickness of the pad 421 may be less than a thickness of the micro-LED 412. In one embodiment, the thickness of the micro-LED 412 may be at least approximately four times greater than a thickness of the pad 421. For example, the thickness of the pad 421 may be approximately 0.5 μm, and the thickness of the micro-LED 412 may be approximately 2 μm or greater.

Referring now to FIGS. 5A and 5B, plan view illustrations of the micro-LED 512 on a pad 521 are shown, in accordance with various embodiments. In the plan view configuration, the micro-LED 512 and the pad 521 provide a box-in-box alignment feature. That is, the positioning of the micro-LED 512 within the footprint of the pad 521 can be used to determine the offset of the micro-LED 512. Knowing the offset of the micro-LED 512 enables more accurate placement of post transfer anode placement on the top of the micro-LED 512 to complete the display device fabrication. For example, in FIG. 5A, the micro-LED 512 is perfectly centered on the pad 521. As such, there is no adjustment needed for the fabrication of the anode on the micro-LED. In FIG. 5B, the micro-LED 512 is offset from the center of the pad 521. As such, the anode fabrication needs to be offset in order to properly form the display device.

It is to be appreciated that such a box-in-box alignment feature is not possible with existing architectures where the pad has a width that is smaller than the width of the micro-LED. In such a configuration, the micro-LED completely blocks the underlying pad. As such, from a top down view, the positioning of the micro-LED relative to the pad cannot be determined. Accordingly, fabrication of the anode on the micro-LED is made more difficult.

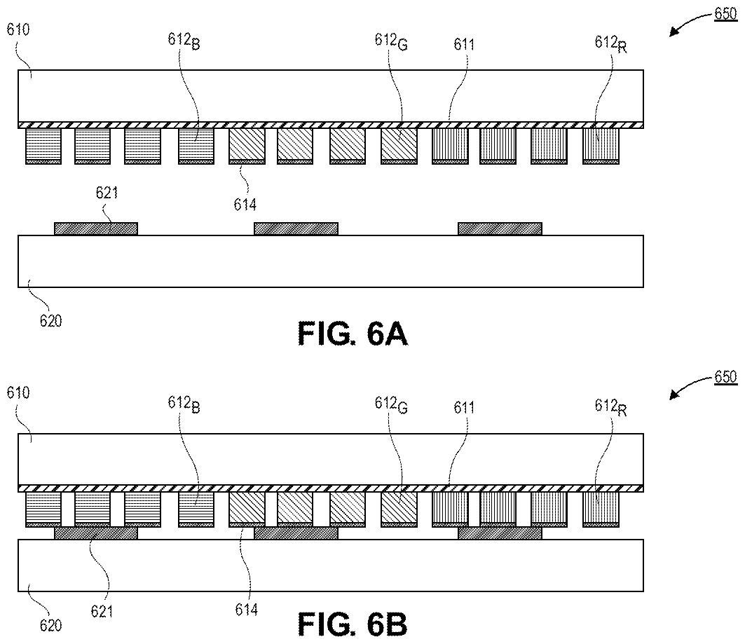

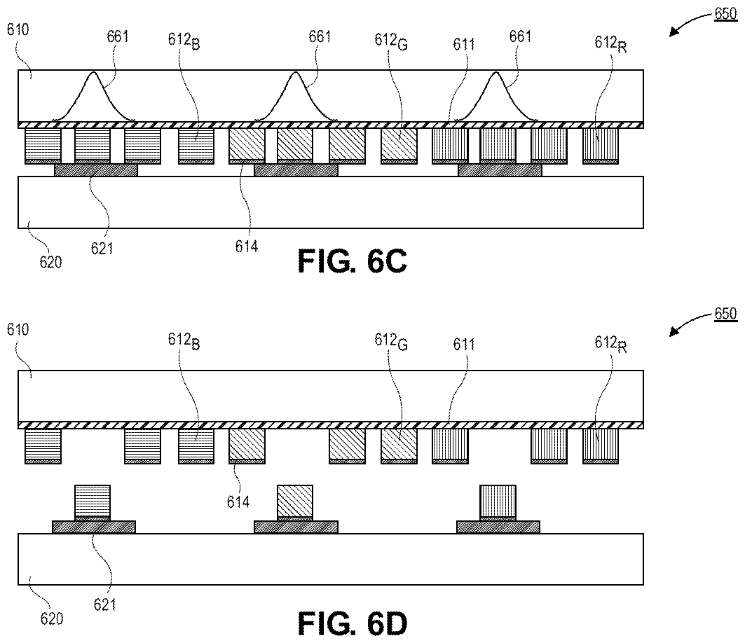

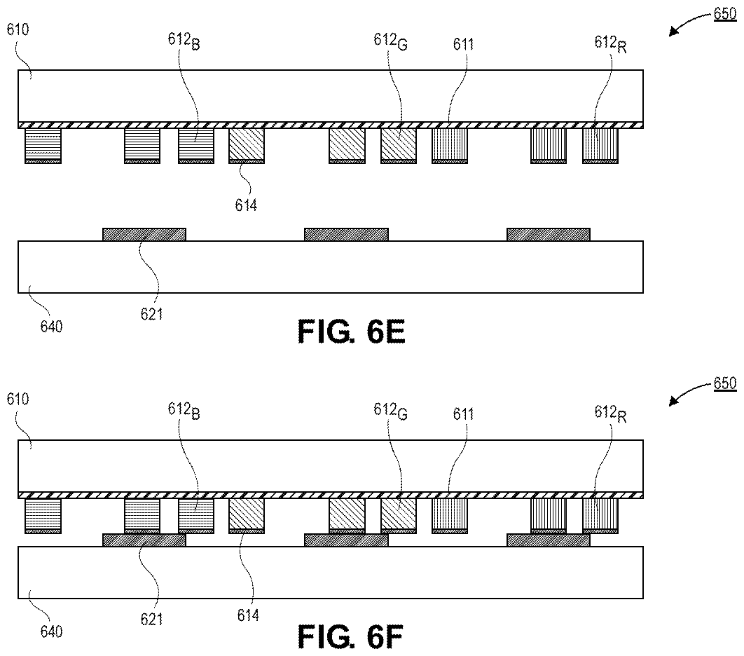

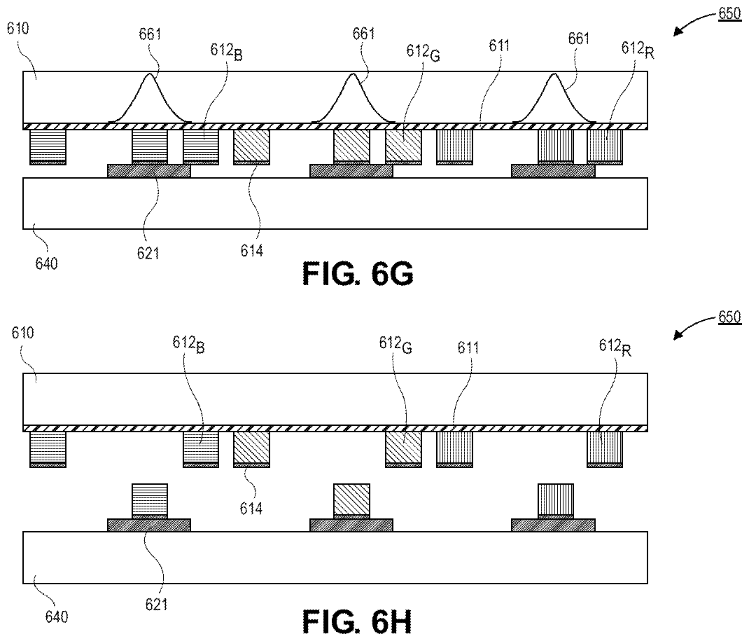

Referring now to FIGS. 6A-6H, a process for fabricating multiple display devices on different backplanes 620 and 640 with the use of a single source wafer 610 is shown, in accordance with an embodiment. As illustrated, the single source wafer 610 may be used to transfer micro-LEDs 612 to different backplanes 620 and 640.

Referring now to FIG. 6A, a cross-sectional illustration of an assembly 650 is shown, in accordance with an embodiment. In an embodiment, the assembly 650 comprises a source wafer 610 and first backplane 620. The source wafer 610 may include micro-LEDs 612 that are attached to the source wafer 610 by a release layer 611. For example, blue micro-LEDs 612_{B}, green micro-LEDs 612_{G}, and red micro-LEDs 612_{R} may be provided on the source wafer 610. The micro-LEDs 612 may include a conductive layer 614 on the bottom surfaces, such as a copper layer. In an embodiment, the first backplane 620 may include a plurality of pads 621. In an embodiment, the width of the pads 621 may be greater than the width of the micro-LEDs 612 on the source wafer 610.

Referring now to FIG. 6B, a cross-sectional illustration of the assembly 650 after the source wafer 610 is displaced towards the first backplane 620 is shown, in accordance with an embodiment. In an embodiment, the source wafer 610 is displaced relative to the first backplane 620 in order to bring the conductive layers 614 into contact with the pads 621. In the illustrated embodiment, the targeted micro-LEDs 612 for transfer are perfectly aligned with the pads 621. However, it is to be appreciated that the targeted micro-LEDs 612 may be offset from the center of the pads 621 in some embodiments.

Referring now to FIG. 6C, a cross-sectional illustration of the assembly 650 after a laser exposure is shown, in accordance with an embodiment. In an embodiment, laser irradiation 661 may be provided over the targeted micro-LEDs 612 in order to release the hold of the release layer 611. The laser may be an IR laser. As shown, the laser pulse 661 may have a Gaussian distribution. It is to be appreciated that the larger pad 621 width allows for improved performance of the laser release process. In part, this is because the pads 621 block the laser exposure from interacting with the underlying circuitry (not shown) below the pads 621. For example, approximately 90% or more of the energy from the laser is blocked by the micro-LED 612 and the pad 621. As shown in FIG. 3, the tail ends of the laser pulse 661 are substantially within a footprint of the pad 621. As such, the laser energy does not propagate through to the underlying circuitry. This prevents damage to the circuitry and enables a more robust device.

Referring now to FIG. 6D, a cross-sectional illustration of the assembly 650 after the source wafer 610 is retracted is shown, in accordance with an embodiment. As shown, the targeted micro-LEDs 612 for transfer remain on the first backplane 620, and the rest of the micro-LEDs 612 remain on the source wafer 610. The remaining micro-LEDs 612 on the source wafer 610 may then be used for transfer to different backplanes.

Referring now to FIG. 6E, a cross-sectional illustration of the assembly 650 after the source wafer 610 is aligned over a second backplane 640 is shown, in accordance with an embodiment. In an embodiment, the second backplane 640 may be substantially similar to the first backplane 620. The second backplane 640 may include pads 621 on which the micro-LEDs 612 can be transferred.

Referring now to FIG. 6F, a cross-sectional illustration of the assembly 650 after the micro-LEDs 612 are brought into contact with the pads 621 is shown, in accordance with an embodiment. In the illustrated embodiment the targeted micro-LEDs 612 for transfer are perfectly aligned with the underlying pads 621. However, it is to be appreciated that the targeted micro-LEDs 612 for transfer may be offset from the center of the pads 621. The larger width of the pads 621 allows for an increased margin for misalignment.

Referring now to FIG. 6G, a cross-sectional illustration of the assembly 650 after a laser release process is shown, in accordance with an embodiment. In an embodiment, the laser release process may be substantially similar to the laser release process described above with respect to FIG. 6C. That is, the laser irradiation 661 may release the targeted micro-LEDs 612 from the release layer 611.

Referring now to FIG. 6H, a cross-sectional illustration of the assembly 650 after the source wafer 610 is retracted is shown, in accordance with an embodiment. In an embodiment, the targeted micro-LEDs 612 for transfer remain on the second backplane 640, and the remaining micro-LEDs 612 are retracted with the source wafer 610. As shown, additional micro-LEDs 612 remain on the source wafer 610. These additional micro-LEDs 612 may then be transferred to additional different backplanes using a similar process.

As can be appreciated from the process flow of FIGS. 6A-6H, micro-LED transfer can be implemented with HVM compatible processing equipment. The increased margin for micro-LED 612 misalignment error allows for fast and efficient transfer of the micro-LEDs 612. Additionally, many micro-LEDs 612 can be transferred substantially in parallel in order to enable the high throughput necessary in an HVM environment.

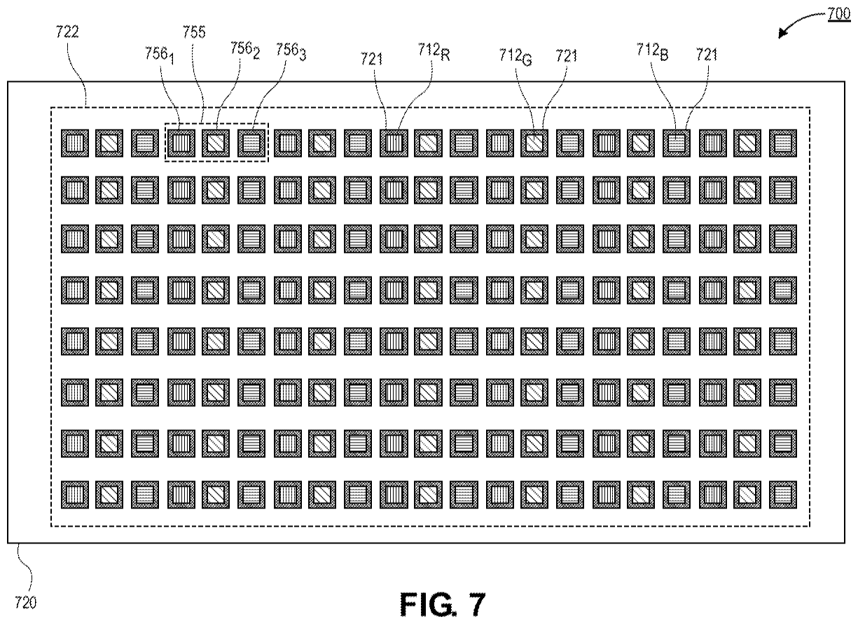

Referring now to FIG. 7, a plan view illustration of a display 700 is shown, in accordance with an embodiment. In an embodiment, the display 700 may comprise a backplane 720, such as a glass backplane 720. The backplane 720 may comprise circuitry 722. In an embodiment, a plurality of pixels 755 may be distributed across a surface of the backplane 720 and coupled to the circuitry 722. Each pixel 755 may include a plurality of subpixels 756 (e.g., subpixels 756₁-756₃). For example, the sub-pixels 756 may comprise a red micro-LED 712_{R}, a green micro-LED 712_{G}, or a blue micro-LED 712_{B}. The micro-LEDs 712 may each be provided over a pad 721 that has a footprint that is larger than a footprint of the micro-LED 712.

In the illustrated embodiment, each pixel 755 comprises a red, green, blue (RGB) pixel arrangement. However, it is to be appreciated that any pixel configuration may be used in accordance with additional embodiments. For example, a single pixel may comprise redundant micro-LEDs, different numbers of micro-LEDs, or different placements and/or patterns of the various micro-LED colors.

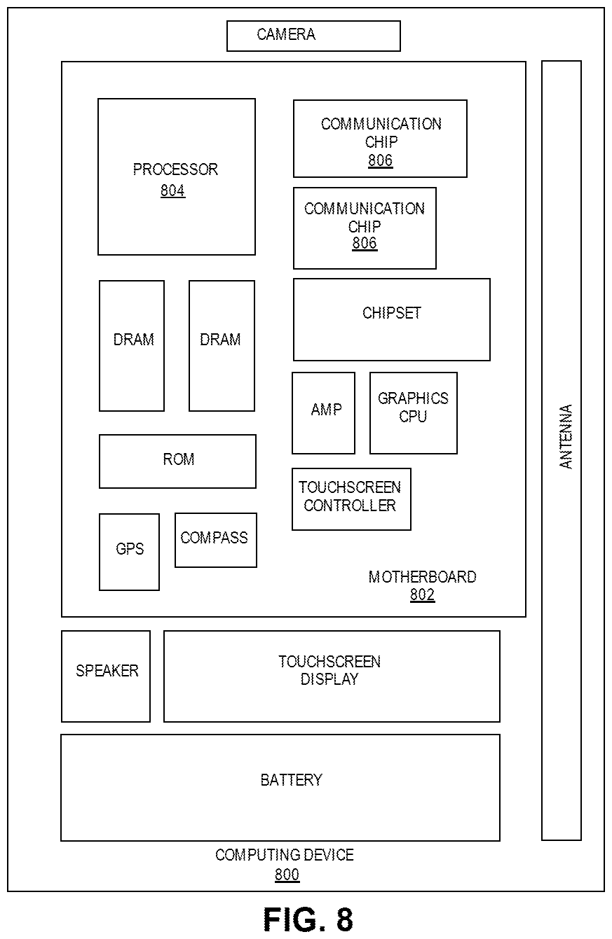

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as W₁-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of a display device that comprises micro-LEDs that are provided on pads of the backplane, where the pads have a larger footprint than the micro-LEDs, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of a display device that comprises micro-LEDs that are provided on pads of the backplane, where the pads have a larger footprint than the micro-LEDs, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a display, comprising: a backplane; circuitry on the backplane; a pad with a first width over the backplane and electrically coupled to the circuitry, wherein the pad comprise a conductive material; and a light emitting diode (LED) coupled to the pad, wherein the LED has a second width that is smaller than the first width.

Example 2: the display of Example 1, wherein the first width is at least 1.5 times larger than the second width.

Example 3: the display of Example 2, wherein the first width is at least 2 times larger than the second width.

Example 4: the display of Examples 1-3, wherein the backplane comprises glass.

Example 5: the display of claim Examples 1-4, wherein the LED is a micro-LED.

Example 6: the display of Examples 1-5, wherein a thickness of the pad is approximately 1 micron thick or less.

Example 7: the display of Example 6, wherein the thickness of the pad is approximately 0.5 microns thick or less.

Example 8: the display of Examples 1-7, wherein the LED comprises a conductive layer, and wherein the conductive layer is coupled to the pad.

Example 9: the display of Example 8, wherein the conductive layer is diffusion bonded to the pad.

Example 10: the display of Examples 1-9, further comprising: a second pad and a second LED over the second pad; and a third pad and a third LED over the third pad.

Example 11: the display of Example 10, wherein the LED, the second LED, and the third LED are part of a single pixel of the display.

Example 12: the display of Examples 1-11, wherein the LED is offset from a center of the pad.

Example 13: the display of Examples 1-12, wherein the LED has a thickness that is approximately 2 microns or less.

Example 14: a method of assembling a display, comprising: providing a backplane with circuitry and a plurality of pads, wherein individual ones of the plurality of pads have a first width; aligning a source wafer to the backplane, wherein the source wafer comprises a plurality of micro light emitting diodes (LEDs), wherein individual ones of the plurality of micro-LEDs have a second width that is smaller than the first width; bringing the plurality of micro-LEDs into contact with the plurality of pads; releasing a first set of micro-LEDs from the source wafer; and retracting the source wafer, wherein a second set of micro-LEDs remain attached to the source wafer.

Example 15: the method of Example 14, wherein the first width is at least 1.5 times larger than the second width.

Example 16: the method of Example 15, wherein the first width is at least 2 times larger than the second width.

Example 17: the method of Examples 14-16, wherein the first set of micro-LEDs are released from the source wafer by exposing a release layer to a laser.

Example 18: the method of Example 17, wherein the laser has a Gaussian distribution, and wherein, for each LED released in the first set of LEDs, approximately 90% of the energy of the laser is provided over one of the pads.

Example 19: the method of Examples 14-18, wherein the first set of LEDs comprise a red LED, a green LED, and a blue LED.

Example 20: the method of Examples 14-19, wherein the second set of micro-LEDs are subsequently attached to a second backplane.

Example 21: the method of Examples 14-20, wherein at least two micro-LEDs contact an individual pad of the plurality of pads when the plurality of micro-LEDs are brought into contact with the plurality of pads.

Example 22: the method of Example 21, wherein only a single micro-LED of the at least two micro-LEDs are released on the individual pad.

Example 23: a display device, comprising: a backplane; circuitry on the backplane; and a plurality of pixels coupled to the circuitry, wherein individual ones of the plurality of pixels comprise: a red subpixel; a green subpixel; and a blue subpixel; and wherein individual ones of the subpixels comprise: a conductive pad with a first width; and a micro light emitting diode (LED) with a second width on the conductive pad, wherein the second width is smaller than the first width.

Example 24: the display device of Example 23, wherein the first width is at least 1.5 times larger than the second width.

Example 25: the display device of Example 23 or Example 24, wherein the micro-LEDs are coupled to the conductive pads with a diffusion bonding process.

What is claimed is:

1. A display, comprising:
a backplane;
circuitry on the backplane;
a pad with a first width over the backplane and electrically coupled to the circuitry, wherein the pad comprise a conductive material; and
a light emitting diode (LED) coupled to the pad, wherein the LED has a second width that is smaller than the first width.

2. The display of claim 1, wherein the first width is at least 1.5 times larger than the second width.

3. The display of claim 2, wherein the first width is at least 2 times larger than the second width.

4. The display of claim 1, wherein the backplane comprises glass.

5. The display of claim 1, wherein the LED is a micro-LED.

6. The display of claim 1, wherein a thickness of the pad is approximately 1 micron thick or less.

7. The display of claim 6, wherein the thickness of the pad is approximately 0.5 microns thick or less.

8. The display of claim 1, wherein the LED comprises a conductive layer, and wherein the conductive layer is coupled to the pad.

9. The display of claim 8, wherein the conductive layer is diffusion bonded to the pad.

10. The display of claim 1, further comprising:
a second pad and a second LED over the second pad; and
a third pad and a third LED over the third pad.

11. The display of claim 10, wherein the LED, the second LED, and the third LED are part of a single pixel of the display.

12. The display of claim 1, wherein the LED is offset from a center of the pad.

13. The display of claim 1, wherein the LED has a thickness that is approximately 2 microns or less.

14. A method of assembling a display, comprising:
providing a backplane with circuitry and a plurality of pads, wherein individual ones of the plurality of pads have a first width;
aligning a source wafer to the backplane, wherein the source wafer comprises a plurality of micro light emitting diodes (LEDs), wherein individual ones of the plurality of micro-LEDs have a second width that is smaller than the first width;
bringing the plurality of micro-LEDs into contact with the plurality of pads;
releasing a first set of micro-LEDs from the source wafer; and
retracting the source wafer, wherein a second set of micro-LEDs remain attached to the source wafer.

15. The method of claim 14, wherein the first width is at least 1.5 times larger than the second width.

16. The method of claim 15, wherein the first width is at least 2 times larger than the second width.

17. The method of claim 14, wherein the first set of micro-LEDs are released from the source wafer by exposing a release layer to a laser.

18. The method of claim 17, wherein the laser has a Gaussian distribution, and wherein, for each LED released in the first set of LEDs, approximately 90% of the energy of the laser is provided over one of the pads.

19. The method of claim 14, wherein the first set of LEDs comprise a red LED, a green LED, and a blue LED.

20. The method of claim 14, wherein the second set of micro-LEDs are subsequently attached to a second backplane.

21. The method of claim 14, wherein at least two micro-LEDs contact an individual pad of the plurality of pads when the plurality of micro-LEDs are brought into contact with the plurality of pads.

22. The method of claim 21, wherein only a single micro-LED of the at least two micro-LEDs are released on the individual pad.

23. A display device, comprising:
a backplane;
circuitry on the backplane; and
a plurality of pixels coupled to the circuitry, wherein individual ones of the plurality of pixels comprise:
a red subpixel;
a green subpixel; and
a blue subpixel; and wherein individual ones of the subpixels comprise:
a conductive pad with a first width; and
a micro light emitting diode (LED) with a second width on the conductive pad, wherein the second width is smaller than the first width.

24. The display device of claim 23, wherein the first width is at least 1.5 times larger than the second width.

25. The display device of claim 23, wherein the micro-LEDs are coupled to the conductive pads with a diffusion bonding process.
